(19) United States
(12) Patent Application Publication
(10) Pub. No.: US 2008/0308937 A1
(43) Pub. Date: Dec. 18, 2008

(54) COPPER-FREE SEMICONDUCTOR DEVICE INTERFACE AND METHODS OF FABRICATION AND USE THEREOF

(75) Inventors: Wilbur Catabay, Saratoga, CA (US); Julian Searle, Ripon, CA (US); Wei-Jen Hsia, Saratoga, CA (US); Milan Prejda, San Jose, CA (US); Rohini Ranganathan, San Jose, CA (US); Lahcene Smati, San Jose, CA (US); Majid Milani, San Jose, CA (US)

Correspondence Address: RAYMOND R. MOSER JR., ESQ.;MOSER IP LAW GROUP, 1030 BROAD STREET, 2ND FLOOR, SHREWSBURY, NJ, 07702, US

(73) Assignee: SVTC TECHNOLOGIES, LLC, San Jose, CA (US)

(21) Appl. No.: 12/138,595

(22) Filed: Jun. 13, 2008

Related U.S. Application Data
(60) Provisional application No. 60/943,996, filed on Jun. 14, 2007.

(51) Int. Cl. H01L 23/52; H01L 21/4763

(52) U.S. Cl. 257/751; 438/627; 257/E23.141; 257/E21.495

(57) ABSTRACT

Embodiments of copper-free semiconductor device interfaces and methods for forming and/or utilizing the same are provided herein. In some embodiments, a semiconductor structure may include a substrate having an exposed copper-containing feature; and a copper-free interface disposed over the substrate and providing a conductive interconnect between the copper-containing feature and an upper surface of the copper-free interface to facilitate electrical coupling of the substrate to a semiconductor device while physically isolating the semiconductor device from the copper-containing feature.

### CROSS-REFERENCE TO RELATED APPLICATIONS

This application claims benefit of U.S. provisional patent application Ser. No. 60/943,996, filed Jun. 14, 2007, which is herein incorporated by reference.

### BACKGROUND OF THE INVENTION

1. Field of the Invention

The present invention generally relates to semiconductor devices, and more particularly, to methods and apparatus for providing a copper-free interface for coupling semiconductor devices.

2. Description of the Related Art

Copper is presently widely used to form wiring structures and interconnects in semiconductor devices having small feature sizes, sometimes referred to as technology nodes (e.g., sub-130 nm technology nodes). For example, copper is widely used in complementary metal oxide semiconductor (CMOS) devices having smaller feature sizes.

In some applications, however, it may be desirable to couple such copper-containing devices with other devices that do not require copper (such as devices having larger feature sizes) or that are physically incompatible with copper (such as devices formed of materials reactive with copper, or in which copper is otherwise a contaminant).

Unfortunately, copper is a highly mobile material that may easily contaminate the devices and/or tools utilized in the fabrication and/or handling of the copper-containing devices in these applications (which may thereby lead to contamination of future substrates being processed by the same equipment). Accordingly, if these tools are to be subsequently used in connection with devices incompatible with copper, extensive cleaning is typically necessary to satisfactorily remove the copper. Such cleaning is expensive and further results in lengthy down-time of the tools during the cleaning process.

Accordingly, device and/or tool contamination has been observed to prevent economically feasible approaches to coupling devices that do not require copper material layers to copper-containing devices (such as CMOS devices that utilize copper).

Therefore, a need exists for an improved method of fabrication and/or handling of copper structures without contaminating tools.

### SUMMARY

The present invention provides a copper-free semiconductor device interface and methods for forming and/or utilizing the same. In some embodiments, a copper-free interface is provided having a non-copper conductive interconnect (such as tungsten) that may be disposed over an exposed copper-containing feature to allow a wide variety of product applications to be formed on the copper-containing feature. Non-limiting examples of devices suitable to be coupled to copper-containing feature include memory applications (such as magnetic random access memory (MRAM), resistive RAM (RRAM), dynamic RAM (DRAM), cross-point RAM, micro-electromechanical systems (MEMS) RAM, or the like), MEMS devices, mirror arrays, or the like, or combinations thereof. In some embodiments, methods of fabrication and/or use of the copper-free interface advantageously facilitates coupling different devices (such as those discussed above) via the copper-free interface while utilizing tools that are not designed to handle copper, or that may undesirably become contaminated with copper during fabrication and/or handling processes.

In some embodiments, a semiconductor structure may include a substrate having an exposed copper-containing feature; and a copper-free interface disposed over the substrate and providing a conductive interconnect between the copper-containing feature and an upper surface of the copper-free interface to facilitate electrical coupling of the substrate to a semiconductor device while physically isolating the semiconductor device from the copper-containing feature.

In some embodiments, a method of forming a semiconductor structure may include providing a substrate having an exposed copper-containing feature; and forming a copper-free interface over the substrate, the copper-free interface providing a conductive interconnect between the copper-containing feature and an upper surface of the copper-free interface to facilitate the coupling of the substrate to a semiconductor device while physically isolating the semiconductor device from the copper-containing feature.

In some embodiments, a method of forming a semiconductor structure may include forming a copper-free interface over a substrate having an exposed copper-containing feature, the copper-free interface providing a conductive interconnect between the copper-containing feature and an upper surface of the copper-free interface to facilitate the electrical coupling of the substrate to a semiconductor device while physically isolating the semiconductor device from the copper-containing feature; and placing the substrate having the copper-free interface in a process chamber that is incompatible with copper-containing materials or that is dedicated to processing substrates incompatible with copper-containing materials to further process the substrate.

### BRIEF DESCRIPTION OF DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a copper-free interface provided in a dual damascene structure in accordance with some embodiments of the invention.

FIG. 2 depicts a copper-free interface provided in a single damascene structure in accordance with some embodiments of the invention.

FIG. 3 depicts a flow chart of a fabrication process in accordance with some embodiments of the invention.

Where possible, identical reference numerals are used herein to designate identical elements that are common to the Figures. The images used in the drawings are simplified for illustrative purposes and are not necessarily depicted to scale.

### DETAILED DESCRIPTION

The present invention provides a copper-free semiconductor device interface and methods for forming and/or utilizing the same. In some embodiments, applications of discrete and non discrete electronic devices that require copper complementary metal oxide semiconductor (CMOS) structures can benefit by this application. For example, in some embodiments, an interface is provided having a copper-free interconnect (i.e., a conductive interconnect) that may be disposed over a copper CMOS structure to allow a wide variety of product applications to be formed on the copper CMOS structure. Non-limiting examples of devices suitable to be coupled to copper CMOS structures include memory applications (such as magnetic random access memory (MRAM), resistive RAM (RRAM), dynamic RAM (DRAM), cross-point RAM, micro-electromechanical systems (MEMS) RAM, or the like), MEMS devices, mirror arrays, or the like, or combinations thereof. In some embodiments, methods of fabrication and/or use of the copper-free interface advantageously facilitates coupling different devices (such as those discussed above) via the copper-free interface while utilizing tools that are not designed to handle copper, or that may undesirably become contaminated with copper during fabrication and/or handling processes.

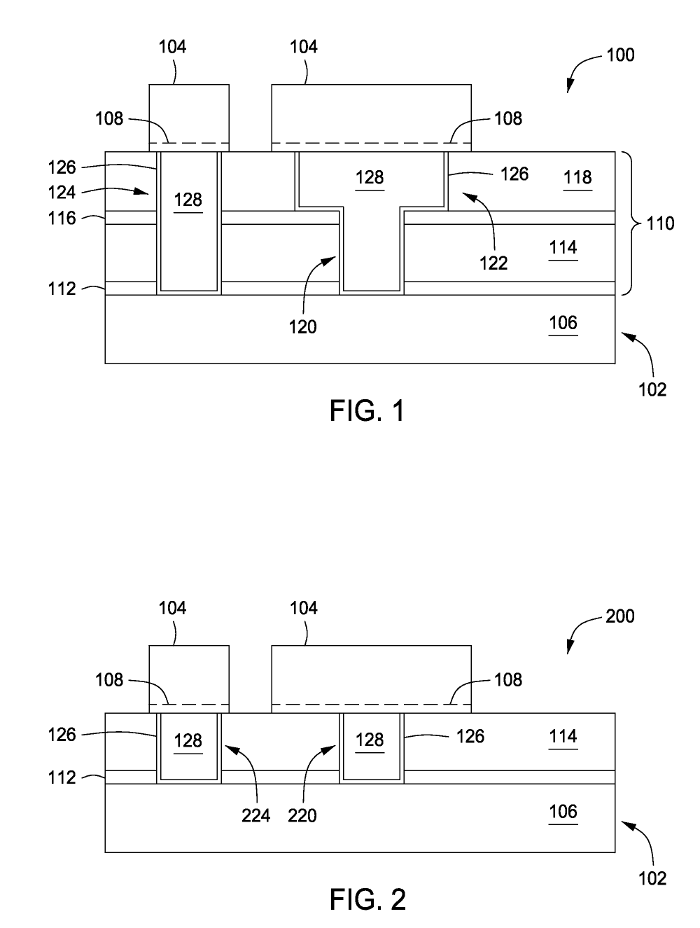

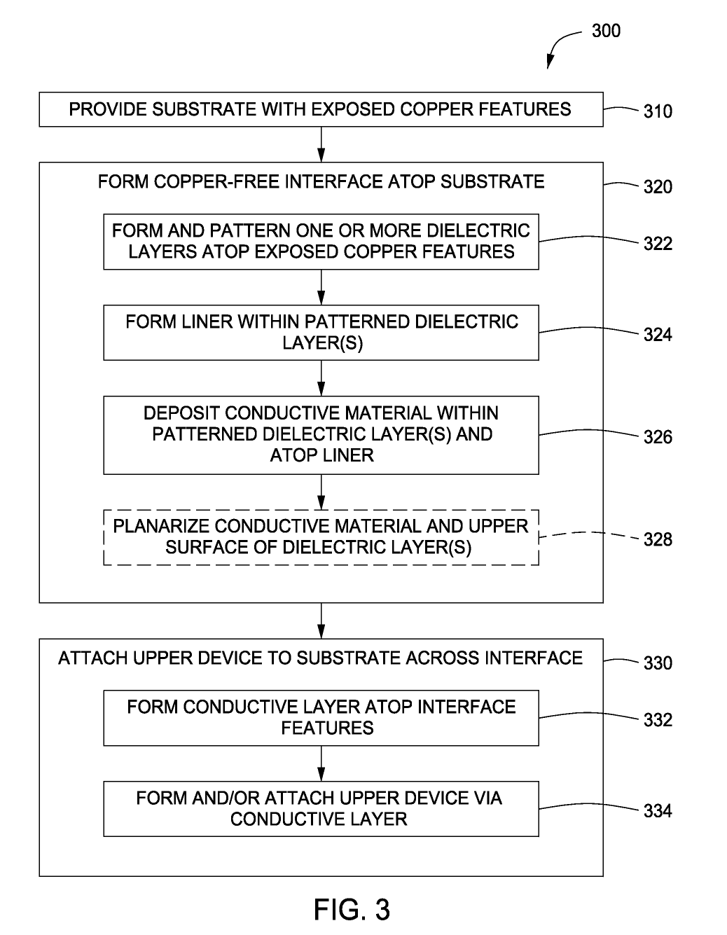

FIG. 1 illustratively depicts a copper-free interface 100 utilized to couple a lower device 102 to an upper device 104 in accordance with some embodiments of the invention. FIG. 2 illustratively depicts a copper-free interface 200 utilized to couple the lower device 102 to the upper device 104 in accordance with some embodiments of the invention. FIG. 3 depicts a method 300 of fabrication of copper-free interfaces (such as copper-free interface 100 or copper-free interface 200 depicted in FIGS. 1 and 2) and is described with reference to FIGS. 1 and 2.

The method 300 begins at 310, where a substrate having exposed copper features is provided. For example, in some embodiments, and as shown in FIGS. 1-2, the substrate may be a lower device 102 having an exposed copper layer 106. It is contemplated that the copper layer 106 may comprise materials in addition to copper (e.g., the exposed copper may be pure copper or copper alloys) and further that the exposed copper may be in the form of islands, pads, vias, trenches, wirelines, or the like formed in a layer of some other material, such as a dielectric. It is further contemplated that any lower device (or portion thereof) having one or more exposed copper layers, features (such as an interconnect), or the like, may be utilized to advantage in the present invention. In some embodiments, the lower device 102 may be a CMOS device (or portion thereof) having one or more exposed copper features (such as the copper layer 106). In some embodiments, the CMOS device may have sub-130 nm features.

Next, at 320, a copper-free interface 100 may be formed or disposed atop the substrate (e.g., over the copper layer 106 of the lower device 102). In some embodiments, the copper-free interface 100 may be formed by forming and patterning one or more dielectric layers atop the exposed copper features, as shown at 322. In some embodiments, as depicted in FIG. 1, a first dielectric layer 114 and a second dielectric layer 118 may be provided. Alternatively, in some embodiments, the first dielectric layer 114 may be provided without the second dielectric layer 118 (as depicted in FIG. 2). It is contemplated that embodiments having either or both of single and dual damascene structures may be fabricated in one or more dielectric layers.

The first and second dielectric layers 114, 118 may comprise any suitable dielectric material for electrically isolating the copper layer 106. Non-limiting examples of suitable dielectric materials generally include any dielectrics suitable for use in semiconductor processing, such as low-k dielectrics, high-k dielectrics, carbon-based dielectrics, silicon-based dielectrics, doped or undoped glasses (such as fluorosilicate glass (FSG), undoped silicate glass (USG)), or the like, or combinations thereof. The first and second dielectric layers 114, 118 may comprise the same or different materials and may be formed by any suitable process, such as spin-on processes, or the like.

Optionally, a barrier layer (such as layer 112) may be formed between the first dielectric layer 114 and the copper layer 106. The barrier layer 112 may function to limit, or prevent, the migration of copper into the first dielectric layer 114. Alternatively or in combination, the barrier layer 112 may function as an etch stop layer during subsequent etching of an interconnect feature into the dielectric layer (as discussed more fully below). The barrier layer 112 may comprise any suitable materials for providing a barrier between the copper layer 106 and the first dielectric layer 114. Non-limiting examples of suitable materials include silicon nitride (SiN), silicon oxynitride (SiON), doped or undoped silicon carbide (SiC, SiCO, or the like), silicon oxide (SiO₂), or the like. The barrier layer 112 may be formed by any suitable process, such as chemical vapor deposition (CVD), physical vapor deposition (PVD), atomic layer deposition (ALD), or the like.

In embodiments where the second dielectric layer 118 is present, a layer 116 may be interposed between the first and second dielectric layers 114, 118, for example to facilitate formation of dual damascene structures therein (as shown in FIG. 1). The layer 116 may comprise similar materials as the barrier layer 112 and may be formed by similar methods. It is contemplated that single or dual damascene structures may be formed in some embodiments without the presence of the interposed layer 116. For example, structures fabricated at 90 nm technology nodes typically do not utilize a middle etch stop layer between the first and second dielectric layers.

The first dielectric layer 114 (and second dielectric layer 118 when present) may then be patterned as desired, for example, by forming a patterned mask atop the dielectric layer(s) and etching the dielectric layers to form desired features therein (such as via 120, via 124, and trench 122 shown in FIG. 1 and via 220 and via 224 shown in FIG. 2). Additional steps, such as to separately mask and form the trench in dual damascene processes (e.g., trench 122 in FIG. 1), stopping the dielectric etch on the layer 116 and/or the barrier layer 112, breaking through the layer 166 (if present), breaking through the barrier layer 112 to expose the underlying copper, and cleaning any residues, if necessary, may also be performed as necessary to define the patterned dielectric layers.

Next, at 324, a liner may be formed within the patterned dielectric layer or layers. For example, a liner 126 may be formed within the pattern and atop the exposed copper as shown in FIGS. 1-2. The liner 126 may comprise any suitable liner material, such as tantalum (Ta), tantalum nitride (TaN), titanium (Ti), titanium nitride (TiN), magnesium (Mg), ruthenium (Ru), niobium (Nb), chromium (Cr), lead (Pb), or the like, or alloys and/or combinations thereof. The liner may be formed by any suitable process such as CVD, PVD, ALD, or the like. It is contemplated that the liner may comprise multiple layers of similar or dissimilar materials, that multiple liners may be provided, or that no liner is provided.

Next, at 326, a non-copper conductive material is deposited within the patterned dielectric layer(s) and atop the liner (when present) to form the copper-free interface 100. For example, in the embodiments shown in FIGS. 1-2, a non-copper conductive material 128 is deposited within the patterned dielectric layer(s) 114,118 to fill the vias (vias 120, 124 in FIG. 1 and vias 220, 224 in FIG. 2) and the trenches (trench 126 in FIG. 1) formed in the patterned dielectric layer(s). Non-limiting examples of suitable non-copper conductive materials include tungsten (W), tantalum (Ta), titanium (Ti), and nitrides thereof (WN, TaN, TiN), aluminum (Al), or the like, or combinations thereof. The non-copper conductive material may be deposited within the patterned dielectric layer(s) by any suitable process, such as CVD, PVD, ALD, or the like. In some embodiments, the non-copper conductive material comprises tungsten deposited by a CVD process.

Optionally, the non-copper conductive material may be planarized with the upper surface of the dielectric layer(s) to provide a substantially flat upper surface of the copper-free interface 100. The planarization process may be any suitable process, such as lapping, chemical mechanical polishing (CMP), electrochemical mechanical polishing (ECMP), or the like. In some embodiments, the non-copper conductive material is planarized by a CMP process to provide a substantially flat upper surface of the copper-free interface 100.

In embodiments where the liner 126 is present, the liner seals the exposed copper (e.g., copper layer 106) in the lower device 102, thereby advantageously allowing further processing and/or handling to occur in tools where copper exposure or contamination is undesirable. In embodiments where the liner 126 is not utilized, the non-copper conductive material 128 seals the exposed copper in the lower device 102, thereby advantageously providing the same benefit. Accordingly, it is contemplated that the process steps recited above up to the point where any exposed copper in the lower device is sealed may be performed in one subset of tools where exposure to copper is permissible and that the process steps recited after the exposed copper in the lower device is sealed may be advantageously performed in a second subset of tools wherein exposure to copper is undesirable.

Next, at 330, an upper device may be attached to the substrate across the copper-free interface. For example, an upper device 104 may be electrically coupled to the lower device 102 via the copper-free interface 100, as shown in FIGS. 1-2 (e.g., through vias, trenches, or other interconnect structures formed therethrough). In some embodiments, as shown at 332, a conductive upper layer may be formed atop the interface features. For example, a conductive layer 108 (shown in phantom in FIGS. 1-2) may be formed atop the non-copper conductive material 128 to provide a location to couple the upper device 104 to the copper-free interface 100 (and thereby, to the lower device 102). The conductive layer 108 may further be utilized for testing the electrical connection to the lower device 102 through the copper-free interface 100 prior to coupling the upper device 104 thereto. Alternatively, and as shown in FIGS. 1-2, the conductive layer 108 may be part of the upper device 104.

Next, at 334, the upper device may be formed on and/or attached to the conductive layer (e.g., conductive layer 108). In some embodiments, processing may continue to fabricate an upper device upon the copper-free interface 100. Alternatively or in combination, a prefabricated upper device (such as any of the devices discussed above) may be coupled to the conductive layer 108 and/or directly to the copper-free interface 100.

Thus, an interface has been provided that may be utilized to couple a lower device to an upper device. Although any upper devices may generally be coupled to the lower device via the provided interface, the present interface is free of copper, thereby advantageously allowing upper devices that do not utilize copper or that are incompatible with copper (e.g., sensitive to copper contamination) to be coupled to a lower device having interconnects or exposed layers comprising copper. Non-limiting examples of devices suitable to be coupled to a lower device having, for example, copper CMOS structures include memory devices, such as magnetic random access memory (MRAM), resistive RAM (RRAM), micro-electromechanical systems (MEMS) RAM, MEMS devices, mirror arrays, or the like, or combinations thereof.

Moreover, the process described above advantageously facilitates division of processing steps between fabrication equipment that is compatible with copper and fabrication equipment that might be undesirably contaminated with copper. Accordingly, in some embodiments, a substrate might be provided having sealed copper features by partial or complete formation of the copper-free interface (e.g., providing a substrate including the patterned dielectric layer(s) having a liner and/or the non-copper conductive material formed within the patterned dielectric layer(s)). Such a substrate may be coupled to the upper device or otherwise further processed utilizing tools in which copper contamination is undesirable.

While the foregoing is directed to some embodiments of the present invention, other and further embodiments of the invention may be devised without departing from the basic scope thereof.

1. A semiconductor structure, comprising:
a substrate having an exposed copper-containing feature; and
a copper-free interface disposed over the substrate and providing a conductive interconnect between the copper-containing feature and an upper surface of the copper-free interface to facilitate electrical coupling of the substrate to a semiconductor device while physically isolating the semiconductor device from the copper-containing feature.

2. The semiconductor structure of claim 1, wherein the copper-free interface further comprises:
one or more dielectric layers disposed above the substrate and having the conductive interconnect formed therein and therethrough.

3. The semiconductor structure of claim 2, wherein the one or more dielectric layers further comprises:
a first dielectric layer disposed above the substrate; and
a second dielectric layer disposed above the first dielectric layer.

4. The semiconductor structure of claim 3, wherein the copper-free interface further comprises:
a layer disposed between the first and second dielectric layers.

5. The semiconductor structure of claim 2, wherein the copper-free interface further comprises:
a barrier layer formed between the substrate and the first dielectric layer.

6. The semiconductor structure of claim 5, wherein the barrier layer comprises at least one of silicon nitride (SiN), silicon oxynitride (SiON), doped or undoped silicon carbide (SiC), or silicon oxide (SiO₂).

7. The semiconductor structure of claim 2, wherein the one or more dielectric layers comprise at least one of low-k dielectrics, high-k dielectrics, carbon-based dielectrics, silicon-based dielectrics, silicate glass (USG), or fluorosilicate glass (FSG).

8. The semiconductor structure of claim 2, wherein the conductive interconnect comprises at least one of a via or trench.

9. The semiconductor structure of claim 2, wherein the conductive interconnect is formed from a non-copper conductive material comprising at least one of tungsten (W), tantalum (Ta), titanium (Ti), nitrogen (N), or Aluminum (Al).

10. The semiconductor structure of claim 2, wherein the copper-free interface further comprises:
a liner formed within the one or more dielectric layers and atop the exposed copper-containing feature, wherein the liner comprises at least one of tantalum (Ta), tantalum nitride (TaN) titanium (Ti), titanium nitride (TiN), magnesium (Mg), ruthenium (Ru), niobium (Nb), chromium (Cr), or lead (Pb).

11. The semiconductor structure of claim 1, wherein the substrate comprises a complementary metal oxide semiconductor (CMOS) device.

12. The semiconductor structure of claim 1, wherein the semiconductor device does not contain copper.

13. The semiconductor structure of claim 1, wherein the semiconductor device comprises at least one of magnetic random access memory (MRAM), resistive RAM (RRAM), dynamic RAM (DRAM), cross-point RAM, micro-electromechanical systems (MEMS) RAM, MEMS devices, or mirror arrays.

14. A method of forming a semiconductor structure, comprising:
providing a substrate having an exposed copper-containing feature; and
forming a copper-free interface over the substrate, the copper-free interface providing a conductive interconnect between the copper-containing feature and an upper surface of the copper-free interface to facilitate the coupling of the substrate to a semiconductor device while physically isolating the semiconductor device from the copper-containing feature.

15. The method of claim 14, wherein forming the copper-free interface further comprises:
forming and patterning one or more dielectric layers above the substrate; and
forming the conductive interconnect by depositing a non-copper conductive material within the patterned one or more dielectric layers.

16. The method of claim 15, wherein forming and patterning the one or more dielectric layers further comprises:
forming a first dielectric layer disposed above the substrate;
forming a second dielectric layer disposed above the first dielectric layer; and
patterning the first and second dielectric layers for providing the conductive interconnect.

17. The method of claim 16, wherein forming the copper-free interface further comprises:
forming a barrier layer between the substrate and the first dielectric layer.

18. The method of claim 15, wherein forming the copper-free interface further comprises:
forming a liner within the one or more dielectric layers and atop the exposed copper-containing feature.

19. The method of claim 15, further comprising:
attaching a semiconductor device to the substrate across the copper-free interface.

20. The method of claim 19, further comprising:
forming a conductive layer between the upper surface and the semiconductor device to facilitate attaching the semiconductor device to the upper surface via the conductive layer.

21. The method of claim 19, further comprising:
planarizing the non copper-containing conductive material and an upper surface of the one or more dielectric layers prior to attaching the semiconductor device to the substrate across the copper-free interface.

22. The method of claim 19, wherein the semiconductor device is at least one of copper-free or incompatible with copper.

23. A method of forming a semiconductor structure, comprising:
forming a copper-free interface over a substrate having an exposed copper-containing feature, the copper-free interface providing a conductive interconnect between the copper-containing feature and an upper surface of the copper-free interface to facilitate the electrical coupling of the substrate to a semiconductor device while physically isolating the semiconductor device from the copper-containing feature; and
placing the substrate having the copper-free interface in a process chamber that is incompatible with copper-containing materials or that is dedicated to processing substrates incompatible with copper-containing materials to further process the substrate.

24. The method of claim 23, further comprising:
attaching a semiconductor device above the copper-free interface in the process chamber, wherein the semiconductor device is at least one of formed from non copper-containing materials or incompatible with copper-containing materials.

25. The method of claim 24, further comprising:
forming a conductive layer between the upper surface of the interface and the semiconductor device.
